(19) United States
(12) Patent Application Publication
(10) Pub. No.: US 2025/0074616 A1
(43) Pub. Date: Mar. 6, 2025

(54) FLYING OBJECT POWER SUPPLY AND METHOD

(71) Applicant: Nippon Telegraph and Telephone Corporation, Tokyo (JP)

(72) Inventors: Masato MARUYAMA, Musashino-shi, Tokyo (JP); Toshihisa MASUDA, Musashino-shi, Tokyo (JP); Jun KATO, Musashino-shi, Tokyo (JP)

(21) Appl. No.: 18/726,600

(22) PCT Filed: Jan. 12, 2022
(86) PCT No.: PCT/JP2022/000713

§ 371 Date: Jul. 3, 2024

(51) Int. Cl. B64D 31/16; B64D 31/14; B64D 45/02; H05K 9/00

(52) U.S. Cl. CPC B64D 31/16; B64D 31/14; B64D 45/02; H05K 9/0007

(57) ABSTRACT

A power feeding device that is connected to a Faraday cage containing a flight vehicle via a conductor and supplies lightning power generated from a lightning surge that has struck to a battery of the flight vehicle, and a ground line that connects the power feeding device and a ground surface are provided, the power feeding device includes a capacitor connected in series between the Faraday cage and the ground line, a lightning arrester connected in parallel to the capacitor, and a step-down converter that steps down a terminal voltage of the capacitor charged by the lightning surge to generate lightning power and supplies the generated lightning power to the battery.

### TECHNICAL FIELD

The present invention relates to a power feeding device for a flight vehicle and a method thereof.

### BACKGROUND ART

In view of an age of frequent lightning accompanying extreme weather, research and development of a technique for controlling lightning and eliminating lightning damage to people and equipment has been conducted.

As one piece of such research, research on a technique for capturing lightning strikes and safely leading the lightning strikes to the ground by flying a drone including a lightning rod and a guide line (ground line) having one end portion grounded has been conducted. However, a general drone cannot withstand a direct hit of lightning strikes, and fails or falls. Therefore, a technique has been devised in which a drone is provided with a metal basket (Faraday cage) to allow bypassing of a lightning current at the time of a direct hit of lightning strikes and protect the drone (Non Patent Literature 1).

### CITATION LIST

### Non Patent Literature

Non Patent Literature 1: Toshihisa Masuda, and three others, “Drone no tairaisei koujyou ni kansuru kisotekikentou (in Japanese) (Basic Study on Improvement of Lightning Resistance of Drones)”, The Institute of Electronics, Information and Communication Engineers, Society Convention, B-4-6, pp. 179, 2021
Non Patent Literature 2: [retrieved on Nov. 10, 2021], Internet <URL: https://hovering.co.jp/unyo/aeroboonair/>
Non Patent Literature 3: Yukihiro Homma, and three others, “Wireless Power Transmission Technology to In-flight Drone with Microwave”, Microwave Workshops & Exhibition 2019, Fr3A-4, Nov. 27, 2019

### SUMMARY OF INVENTION

### Technical Problem

A general drone has a power storage mechanism such as a battery inside the drone and flies by being supplied with power from the power storage mechanism. However, in a case where the drone is used for applications such as capturing of lightning strikes, a wire (power supply line) is pulled up from the ground as in Non Patent Literature 2, and thus a load on the drone is large, and a flight time may be limited.

Non Patent Literature 3 discloses a technique of wirelessly feeding power from the ground to a drone using microwaves. However, in this technique, the intensity of microwaves is weakened and thus sufficient power cannot be supplied in a case in which the altitude at which the drone flies is high.

The present invention has been made in view of these problems, and an object of the present invention is to provide a power feeding device for a flight vehicle and a method thereof capable of flying a drone for a time longer than a limitation due to the capacity of a battery built into the drone.

### Solution to Problem

A power feeding device for a flight vehicle according to an aspect of the present invention includes: a power feeding device that is connected to a Faraday cage containing a flight vehicle via a conductor and supplies lightning power generated from a lightning surge that has struck to a battery of the flight vehicle; and a ground line that connects the power feeding device and ground surface.

Further, a power feeding method for a flight vehicle according to an aspect of the present invention is a method of feeding power to a flight vehicle performed by a power feeding device, the method including: charging a capacitor connected in series between a Faraday cage and a ground line by a lightning surge that has struck the Faraday cage containing a flight vehicle; stepping down a terminal voltage of the capacitor to generate lightning power; and supplying the lightning power to the flight vehicle.

### Advantageous Effects of Invention

According to the present invention, it is possible to provide a power feeding device for a flight vehicle and a method thereof capable of flying a drone for a flight time longer than a limitation due to the capacity of a battery built into the drone.

### BRIEF DESCRIPTION OF DRAWINGS

FIG. 1 is a diagram schematically illustrating a configuration example of a lightning guiding system according to an embodiment of the present invention.

FIG. 2 is a diagram illustrating a configuration example of a power feeding device illustrated in FIG. 1.

FIG. 3 is a diagram illustrating a configuration example of a step-down converter illustrated in FIG. 2.

FIG. 4 is a diagram illustrating another configuration example of the power feeding device illustrated in FIG. 2.

FIG. 5 is a diagram schematically illustrating another configuration example of an insulating panel illustrated in FIG. 1.

FIG. 6 is a flowchart illustrating a processing procedure of an example of a power feeding method for feeding power to a flight vehicle illustrated in FIG. 1.

### DESCRIPTION OF EMBODIMENTS

Hereinafter, embodiments of the present invention will be described using the drawings. The same reference numerals are given to the same components in the plurality of drawings, and the description thereof will not be repeated.

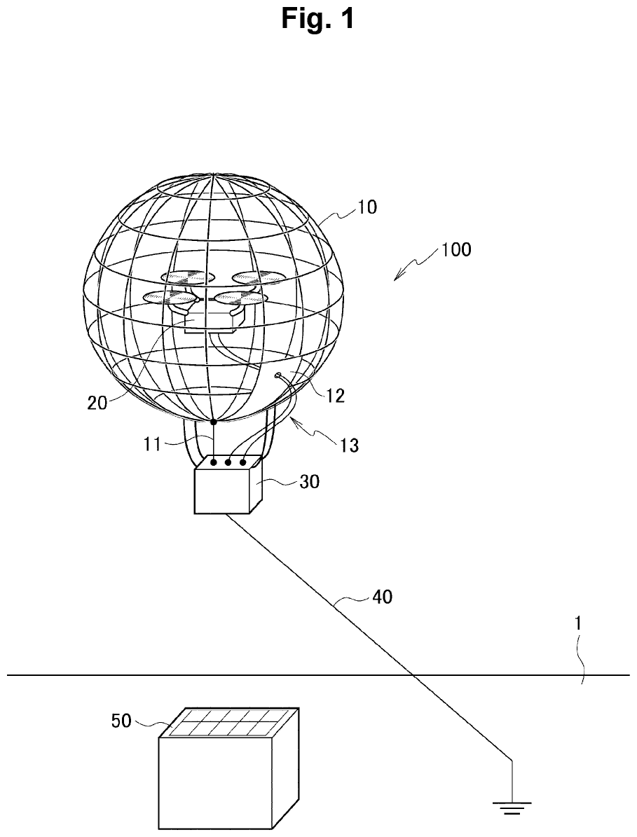

FIG. 1 is a diagram schematically illustrating a configuration example of a lightning guiding system using a power feeding device for a flight vehicle according to an embodiment of the present invention. The lightning guiding system 100 illustrated in FIG. 1 captures lightning using a flight vehicle (drone). The flight vehicle converts a part of the captured lightning surge into power and uses the power for flight of the flight vehicle. The lightning surge is a harmful overvoltage or overcurrent instantaneously generated at the time of a lightning strike.

The power feeding device for the flight vehicle used by the lightning guiding system 100 includes a power feeding device 30 and a ground line 40. An example in which the power feeding device 30 illustrated in FIG. 1 has a function of converting microwaves emitted from a power transmitter 50 on the ground into power and supplying the power to a battery (not illustrated) of the flight vehicle 20 is illustrated.

Note that power transmitter 50 that emits microwaves is not an essential functional component. The battery (not illustrated) of the flight vehicle 20 and the power transmitter 50 may be connected by two power supply lines (not illustrated) to supply power. In addition, the power transmitter 50 and the two power supply lines may not be provided.

That is, the power feeding device for the flight vehicle according to the present embodiment can also be applied to a lightning guiding system having a configuration (first embodiment) in which the power transmitter 50 that emits microwaves or the two power supply lines are not provided. First, the first embodiment will be described.

### First Embodiment

The power feeding device for the flight vehicle according to the first embodiment of the present invention includes a power feeding device 30 and a ground line 40.

The power feeding device 30 is connected to a Faraday cage 10 containing a flight vehicle 20 via a conductor 11 and supplies lightning power generated from a lightning surge that has struck lightning to a battery of the flight vehicle 20.

The Faraday cage 10 is a space surrounded by a conductor or a conductor basket or vessel to be used to create such a space. When lightning strikes the Faraday cage, electric power lines cannot enter the inside of the Faraday cage 10 surrounded by the conductor, and therefore, the external electric field is blocked and the potential inside is all kept equal.

The flight vehicle 20 is contained in the Faraday cage 10 and flies between a lightning originating point (not illustrated) that generates lightning and a ground surface 1 together with the Faraday cage 10. The flight vehicle 20 is fixed to the Faraday cage 10 by, for example, a support (not illustrated).

The flight vehicle 20 is a wireless flight vehicle generally called a drone, and usually flies by remote control of a drone pilot (not illustrated) on the ground. The flight vehicle 20 and a remote controller (not illustrated) operated by a drone pilot are wirelessly connected.

The flight vehicle 20 flies while generating lift by rotating a propeller or the like with power of a built-in battery (not illustrated). Accordingly, a general flight vehicle cannot fly while consuming power exceeding the capacity of the battery thereof.

As illustrated in FIG. 1, the power feeding device 30 may be locked to a lower portion of the Faraday cage 10 with an insulated wire (reference numeral is omitted) or the like, like a gondola of a balloon.

The power feeding device 30 and the flight vehicle 20 are connected by two power feeding lines 13. The power feeding lines 13 pass through a central portion of the insulating panel 12 covering one range surrounded by longitude lines and latitude lines of the Faraday cage 10. The material of the insulating panel 12 is, for example, a ceramic or the like and increases the withstand voltage between the power feeding lines 13 and the Faraday cage. Note that the configuration for increasing the withstand voltage is not limited to this example. Other configurations will be described later.

The ground line 40 connects the power feeding device 30 and the ground surface 1. The lightning surge that has struck the Faraday cage 10 is guided to the ground via the conductor 11, the power feeding device 30, and the ground line 40.

### (Power Feeding Device)

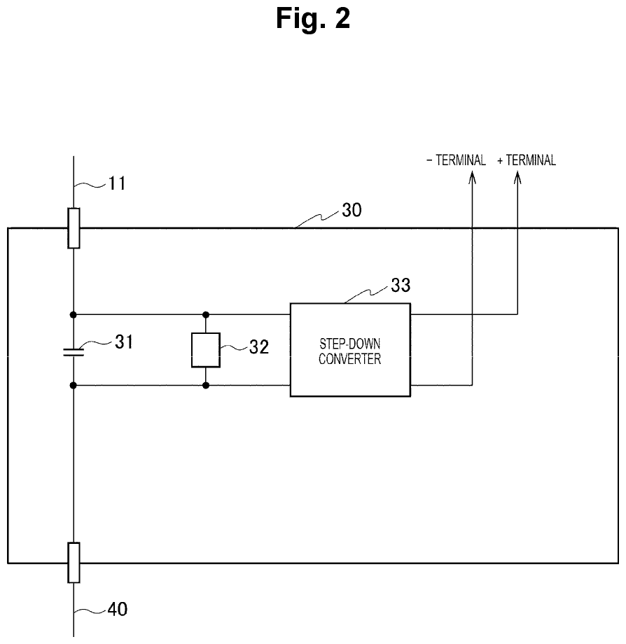

FIG. 2 is a diagram illustrating a configuration example of the power feeding device 30. The power feeding device 30 includes a capacitor 31, a lightning arrester 32, and a step-down converter 33.

The capacitor 31 is connected between the conductor 11 and the ground line 40. The rectangle connected to the conductor 11 is a terminal provided in the housing of the power feeding device 30 and provides insulation between the housing and the conductor 11. A terminal (reference numeral is omitted) of the capacitor 31 on the side of the Faraday cage 10 is electrically connected to the conductor 11. On the other hand, a terminal (rectangle) of the capacitor 31 on the side of the ground line 40 is insulated from the housing of the power feeding device 30 and is electrically connected to the ground line 40. The housing of the power feeding device 30 may be made of an insulator (for example, ceramics or the like).

When lightning strikes the Faraday cage 10, the lightning surge flows through the path of Faraday cage 10→conductor 11→capacitor 31→ground line 40→ground. This lightning surge charges the capacitor 31.

For example, when it is assumed that the capacitance of the capacitor 31 is 0.1 F and the charge amount Q of the lightning surge is 100 C, the terminal voltage V of the capacitor 31 is 1 KV. Assuming as above, the energy W stored in the capacitor 31 can be calculated as 50 KJ by the following expression.

### [Math. 1]

$$W = \frac{1}{2} QV \qquad ( 1 )$$

Since 1 Wh is 1 Wh=3600 J, 50 KJ is about 13.9 Wh. This power can extend the flight time of the flight vehicle 20.

The lightning arrester 32 is connected in parallel to the capacitor 31. The lightning arrester 32 instantaneously changes from high resistance to low resistance with respect to an overvoltage such as a lightning surge, and curbs the overvoltage of the lightning surge. The lightning arrester 32 incorporates one or more nonlinear elements.

As the nonlinear element, for example, any of a metal oxide varistor (MOV), a gas-filled discharge tube (GDT), an avalanche breakdown diode (ABD), a surge protection thyristor, and the like can be used.

A voltage at which the lightning arrester 32 changes from high resistance to low resistance is set to a voltage lower than the withstand voltage of the capacitor 31. In a case in which the withstand voltage of the capacitor 31 is assumed to be 2.2 KV, the voltage thereof is set to, for example, 1.5 KV. Therefore, the capacitor 31 is not destroyed by the lightning surge.

The step-down converter 33 steps down the terminal voltage of the capacitor 31 charged by the lightning surge to generate a lightning power and supplies the generated lightning power to the battery of the flight vehicle 20. A withstand voltage of the step-down converter 33 on the side of the capacitor 31 is set to a voltage higher than the voltage at which the lightning arrester 32 changes from high resistance to low resistance. Assuming as described above, an input rated voltage of the step-down converter 33 is set to, for example, 1.6 KV.

As described above, the power feeding device 30 includes the capacitor 31 connected in series between the Faraday cage 10 and the ground line 40, the lightning arrester 32 connected in parallel to the capacitor 31, and the step-down converter 33 that generates lightning power by stepping down the terminal voltage of the capacitor 31 charged by a lightning surge and supplies the generated lightning power to the battery of the flight vehicle 20. As a result, it is possible to provide the power feeding device for a flight vehicle capable of flying the flight vehicle for a time longer than a limitation due to the capacity of a battery built into the flight vehicle 20.

### (Step-Down Converter)

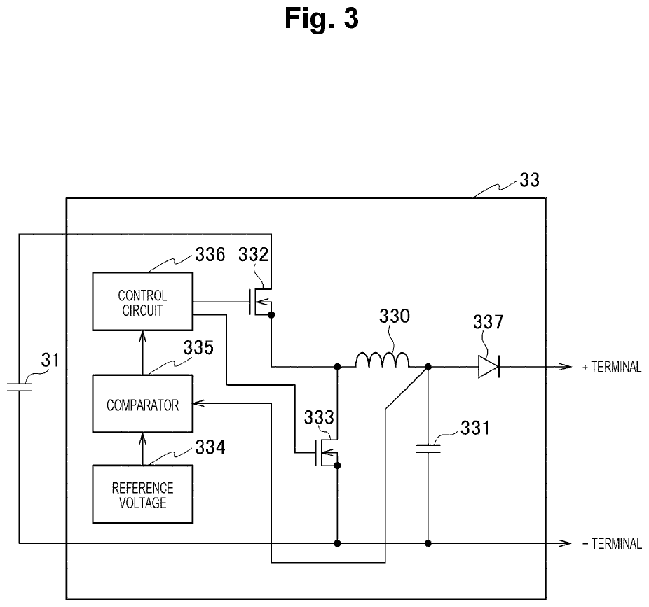

FIG. 3 is a diagram illustrating a configuration example of the step-down converter 33. The step-down converter 33 includes a coil 330, a smoothing capacitor 331, a first switch 332, a second switch 333, a reference voltage 334, a comparator 335, a control circuit 336, and a backflow prevention diode 337.

The step-down converter 33 illustrated in FIG. 3 is a synchronous rectification type step-down converter. An asynchronous rectification type is different in that the second switch 333 is replaced with a diode.

In a case in which the capacitor 31 is charged with a lightning surge, when the first switch 332 is turned on, a current flows from the capacitor 31 to the coil 330, and the current is converted into magnetic energy and accumulated in the coil 330. At this time, the second switch 333 is turned off. The first switch 332 and the second switch 333 are exclusively turned on.

Subsequently, when the second switch 333 is turned on and the first switch 332 is turned off, the energy accumulated in the coil 330 is released to the smoothing capacitor 331. Since the operation is performed in this manner, desired energy (lightning power) can be extracted from the capacitor 31 by controlling a time width (pulse width) for turning on the first switch 332. That is, the terminal voltage of the smoothing capacitor 331 can be stepped down to a desired voltage.

The comparator 335 outputs a comparison result obtained by comparing the terminal voltage of the smoothing capacitor 331 with the reference voltage 334 related to the terminal voltage to the control circuit 336. In a case in which the terminal voltage of the smoothing capacitor 331 is lower than the reference voltage 334, the comparator 335 outputs a comparison result in which the time during which the first switch 332 is turned on increases. On the other hand, in a case in which the terminal voltage of the smoothing capacitor 331 is higher than the reference voltage 334, a comparison result in which the time during which the first switch 332 is turned on decreases is output.

The control circuit 336 controls a time width for turning on each of the first switch 332 and the second switch 333 on the basis of the comparison result. That is, the reference voltage 334, the comparator 335, and the control circuit 336 constitute the step-down converter 33 that performs pulse width modulation (PWM) control.

In this manner, the step-down converter 33 performs PWM control to generate lightning power. Accordingly, the voltage of the battery of flight vehicle 20 can be stabilized.

As described above, the power feeding device for a flight vehicle according to the first embodiment of the present invention includes the power feeding device 30 that is connected to the Faraday cage 10 containing the flight vehicle via the conductor 11 and supplies lightning power generated from a lightning surge that has struck to the battery of the flight vehicle 20, and the ground line 40 that connects the power feeding device 30 and the ground surface 1. As a result, since the lightning power generated from the lightning surge is supplied to the battery of the flight vehicle 20, it is possible to provide the power feeding device for a flight vehicle capable of flying a drone for a time longer than a flight time limited by the capacity of a battery built in the drone.

Next, a power feeding device for a flight vehicle which includes the power transmitter 50 (FIG. 1) according to a second embodiment of the present invention will be described.

### Second Embodiment

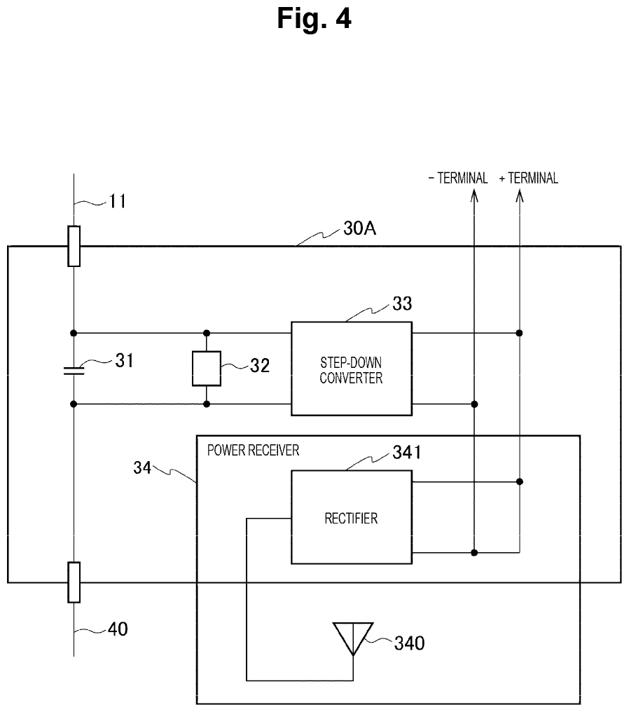

FIG. 4 is a diagram illustrating a configuration example of a power feeding device 30A according to the second embodiment. The power feeding device 30A illustrated in FIG. 4 is different from the power feeding device 30 (FIG. 2) of the first embodiment in that it includes a power receiver 34.

The power receiver 34 includes a power receiving antenna 340 and a rectifier 341.

The power receiving antenna 340 receives microwaves transmitted from the power transmitter 50. The power receiving antenna 340 is, for example, an array antenna having a planar shape and is disposed on the lower surface of the power feeding device 30A.

The rectifier 341 converts the microwaves received through the power receiving antenna 340 into DC power. The voltage of the DC power is set to a voltage sufficient to charge the battery of the flight vehicle 20. In a case in which the battery of the flight vehicle 20 includes, for example, four cells (3.7 V×4) of a lithium polymer battery, the voltage thereof is set to, for example, about 15 V.

The power transmitter 50 is disposed on the ground and transmits (power-transmits) microwaves. Microwaves have a frequency of 300 MHz to 300 GHz and are radio waves for power transmission that can also transmit power. A power transmission antenna (reference numeral omitted) is disposed above the power transmitter 50 to transmit microwaves to the power feeding device 30A. Microwaves can be beam-controlled to track a moving flight vehicle. A technique of wirelessly feeding power to a flight vehicle using microwaves is described in Non Patent Literature 2.

The power feeding device 30A according to the second embodiment includes the power receiver 34 that converts microwaves transmitted from the ground into power for flying the flight vehicle 20. As a result, in addition to the aforementioned effect that the flight time can be extended, an effect of reducing the load on the flight vehicle 20 can also be obtained since power is wirelessly supplied to the flight vehicle 20.

### (Modified Example of Insulating Panel)

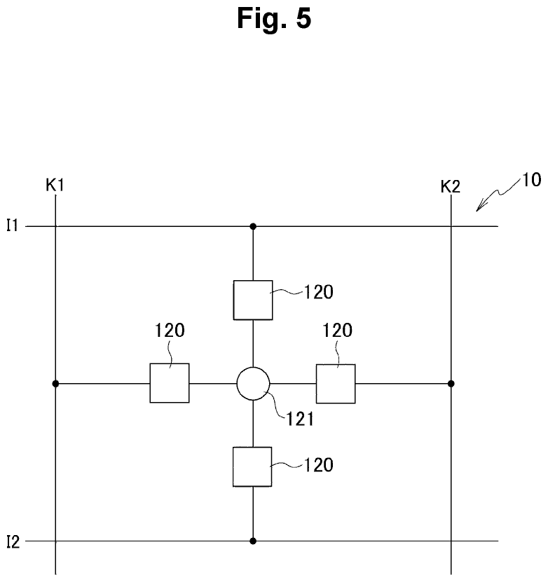

FIG. 5 is a diagram schematically illustrating another configuration example of the insulating panel 12.

In FIG. 5, K1 and K2 are arbitrary longitude lines of the Faraday cage 10, and I1 and I2 are arbitrary latitude lines thereof. A rectangle indicated by a reference numeral 120 is an insulator, and a reference numeral 121 is an insulator hole (ring) that supports the power feeding line 13.

As illustrated in FIG. 5, the insulator hole 121 supporting the power feeding line 13 through which power from the power feeding device 30 is supplied to the flight vehicle 20 may be held by four insulators from each of the longitude lines K1 and K2 and the latitude lines I1 and I2 of the Faraday cage 10. Even with this configuration, the same operation and effect as those of the insulating panel 12 (FIG. 1) can be obtained.

Note that the arbitrary longitude lines K1 and K2 may be any longitude lines as long as they are adjacent to each other. In addition, the arbitrary latitude lines I1 and I2 may be any latitude lines as long as they are the lower half of the Faraday cage 10. In addition, the number of insulators 120 is not limited to four. The hole 121 need not necessarily be supported at four points.

As described above, the lightning guiding system 100 according to the present embodiment includes the power feeding line through which power is supplied from the power feeding device 30 to the flight vehicle 20, and the power feeding line is supported by the insulator hole 121 to pass through the central portion of one range surrounded by longitude lines K and latitude lines I of the Faraday cage 10. As a result, the withstand voltage between the power feeding line and the Faraday cage can be increased.

### (Power Feeding Method)

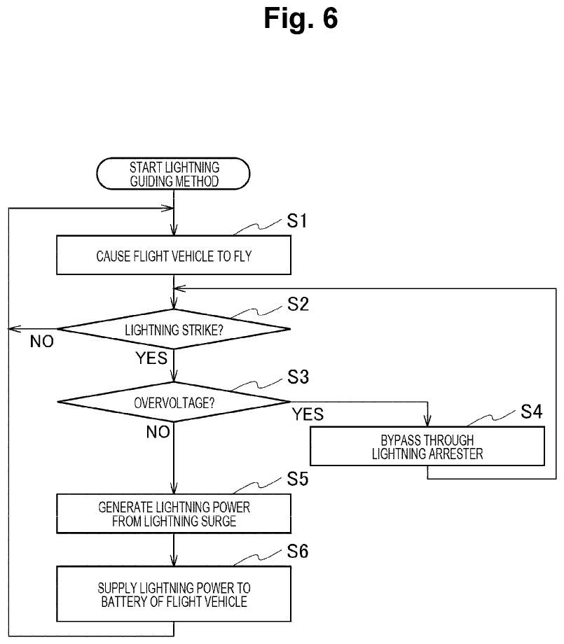

FIG. 6 is a flowchart illustrating a processing procedure of a power feeding method of the lightning guiding system 100. The power feeding method according to the first embodiment will be described with reference to FIG. 6.

The lightning guiding system 100 causes the flight vehicle 20 contained in the Faraday cage 10 to fly (step S1). Flight vehicle 20 is operated by an operator on the ground to fly. The flight vehicle 20 flies with the power of a built-in battery.

Lightning strikes the Faraday cage 10 during flight (YES in step S2).

In a case in which the lightning surge that has struck is an overvoltage exceeding the withstand voltage of the capacitor 31 (YES in step S3), the lightning surge is bypassed by the lightning arrester 32 (step S4). Accordingly, the capacitor 31 and the step-down converter 33 are not destroyed by the lightning surge.

The power feeding device 30 generates lightning power from the lightning surge within the withstand voltage of the capacitor 31 (step S5).

Next, the power feeding device 30 supplies the generated lightning power to the battery of the flight vehicle 20 (step S6).

As described above, the power feeding method according to the first embodiment is a method of feeding power to the flight vehicle 20 performed by the power feeding device 30, in which the capacitor 31 connected in series between the Faraday cage 10 and the ground line 40 is charged by the lightning surge that has struck the Faraday cage 10 containing the flight vehicle 20, the terminal voltage of the capacitor 31 is stepped down to generate lightning power, and the lightning power is supplied to the flight vehicle 20. As a result, it is possible to provide the power feeding method for a flight vehicle capable of flying the flight vehicle for a time longer than a limitation due to the capacity of the battery built into the flight vehicle 20. Therefore, it is possible to reduce traffic of the flight vehicle 20 between the ground surface 1 and the sky due to a battery shortage and efficiently capture a lightning strike.

In addition, since the power feeding device 30A according to the second embodiment does not require two power supply lines connected to the ground, the load on the flight vehicle 20 can be reduced. As a result, the flight vehicle 20 can stably fly without being agitated by the weight of the power supply line or wind.

Although the step-down converter 33 has been described as an example of a synchronous rectification type step-down converter in the above examples, the present invention is not limited to this example. The step-down converter 33 may be an asynchronous rectification type. Further, PWM control may not be performed. Further, the shape of the Faraday cage 10 is not necessarily a sphere. Further, the smoothing capacitor 331 may be replaced with a secondary battery.

In addition, as described in the above embodiments, the power feeding device for a flight vehicle according to the present invention can be applied to any of the lightning guiding system (first embodiment) that does not feed power from the ground surface 1, the lightning guiding system (second embodiment) that wirelessly feeds power for flying the flight vehicle 20 from the ground surface 1, and a lightning guiding system that feeds power from the ground surface 1 to the flight vehicle 20 through two power supply lines although not illustrated and described. According to the present invention, it is possible to provide a power feeding device for a flight vehicle and a method thereof capable of flying the flight vehicle for a time longer than a limitation due to the capacity of a battery built into the flight vehicle 20 in any of the lightning guiding systems.

As described above, it is a matter of course that the present invention includes various embodiments and the like not described herein. Therefore, the technical scope of the present invention is defined only by the matters specifying the invention according to the claims appropriate from the above description.

### REFERENCE SIGNS LIST

1 Ground surface
10 Faraday cage
11 Conductor
12 Insulating panel (insulator)
13 Power feeding line
20 Flight vehicle
30, 30A Power feeding device
31 Capacitor
32 Lightning arrester
33 Step-down converter
34 Power receiver
40 Ground line
50 Power transmitter
100 Lightning guiding system
120 Insulator (insulator)
K1, 2 Longitude line
I1, 2 Latitude line

1. A power feeding device for a flight vehicle, comprising:
a power feeding device that is connected to a Faraday cage containing a flight vehicle via a conductor and supplies lightning power generated from a lightning surge that has struck to a battery of the flight vehicle; and
a ground line that connects the power feeding device and ground surface.

2. The power feeding device for a flight vehicle according to claim 1,
wherein the power feeding device includes:
a capacitor connected in series between the Faraday cage and the ground line;
a lightning arrester connected in parallel to the capacitor; and
a step-down converter that steps down a terminal voltage of the capacitor charged by the lightning surge to generate the lightning power and supplies the generated lightning power to the battery.

3. The power feeding device for a flight vehicle according to claim 2,
comprising a power feeding line through which the lightning power is supplied from the power feeding device to the flight vehicle, wherein
the power feeding line is connected to the battery via an insulator hole provided in a part of the Faraday cage.

4. The power feeding device for a flight vehicle according to claim 2, wherein
the step-down converter generates the lightning power by performing PWM control.

5. The power feeding device for a flight vehicle according to claim 1, wherein
the power feeding device includes a power receiver that converts microwaves transmitted from the ground into power.

6. A power feeding method for a flight vehicle performed by a power feeding device, the power feeding method comprising:
charging a capacitor connected in series between a Faraday cage and a ground line by a lightning surge that has struck the Faraday cage containing a flight vehicle;
stepping down a terminal voltage of the capacitor to generate lightning power; and
supplying the lightning power to the flight vehicle.
